(19) United States
(12) Patent Application Publication
(10) Pub. No.: US 2026/0247877 A1
(43) Pub. Date: Aug. 20, 2026

(54) METHODS OF FORMING SEMICONDUCTOR LAYER STACKS COMPRISING AT LEAST A PORTION OF A VERTICAL CHANNEL TRANSISTOR STRUCTURE

(71) Applicant: ASM IP Holding B.V., Almere (NL)

(72) Inventors: Shahram Ghanad Tavakoli, Chandler, AZ (US); Amir Kajbafvala, Chandler, AZ (US); Frederick Aryeetey, Phoenix, AZ (US)

(21) Appl. No.: 19/536,562

(22) Filed: Feb. 11, 2026

Related U.S. Application Data
(60) Provisional application No. 63/758,777, filed on Feb. 14, 2025.

(51) Int. Cl. H10P 14/24; H10D 30/01

(52) U.S. Cl. CPC H10P 14/24; H10D 30/0227

(57) ABSTRACT

Methods of forming semiconductor layer stacks comprising at least a portion of a vertical channel transistor structure are disclosed. The methods disclosed include depositing one or more carbon doped silicon layer between a doped layer and a channel layer to form one or more blocking layers to mitigate dopant diffusion into the channel layer.

### CROSS-REFERENCE TO RELATED APPLICATIONS

This application is a nonprovisional of, and claims priority to and the benefit of, U.S. Provisional Patent Application No. 63/758,777, filed Feb. 14, 2025 and entitled “METHODS OF FORMING SEMICONDUCTOR LAYER STACKS COMPRISING AT LEAST A PORTION OF A VERTICAL CHANNEL TRANSISTOR STRUCTURE,” which is hereby incorporated by reference herein.

### FIELD

The present disclosure relates generally to the field of semiconductor processing methods, associated structures, and to the field of device and integrated circuit manufacture. More particularly the present disclosure generally relates to methods of forming semiconductor layer stacks employed in the fabrication of vertical channel transistor structures.

### BACKGROUND

Vertical channel transistors (VCTs) are a type of transistor where the current flows vertically through the device, rather than horizontally as in traditional planar transistors. The vertical design can offer several advantages over planar devices, particularly in terms of miniaturization and performance. In addition, VCTs can allow for shorter channel lengths, which can be crucial for scaling down device sizes.

One of the features of VCTs is their high performance. Vertical channel transistors can handle high currents and voltages more efficiently than certain planar transistors. For example, vertical channel field-effect transistors (V-FETs) demonstrate improved on-resistance and frequency response, making V-FETs suitable for high-power applications. Additionally, VCTs can be made from various semiconductor materials, including, but limited to, silicon and compound semiconductors materials, for example, Si, SiGe, GaAs, and InP. These materials can enhance the device's performance characteristics, such as current handling capability and energy band gap.

However, despite their advantages, vertical channel transistors also face a number of challenges. Managing heat dissipation in VCTs can be challenging, and may require advanced cooling solutions. In addition, fabricating VCTs can be more complex and costly compared with traditional planar transistors. Accordingly, improved fabrication processes for vertical channel transistor structures are desirable.

Any discussion, including discussion of problems and solutions set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods of forming semiconductor layer stacks comprising at least a portion of vertical channel transistor structures. The semiconductor layer stacks include blocking layers comprising carbon doped silicon layers that are configured to reduced dopant migration into a channel layer.

In accordance with examples of the disclosure a method of forming a semiconductor layer stack comprising at least a portion of a vertical channel transistor structure is disclosure, the method comprising: seating a substrate in a reaction chamber, depositing a doped silicon layer over the substrate, depositing a channel layer over the substrate, and depositing a carbon doped silicon layer between the doped silicon layer and the channel layer. In such a method, the carbon doped silicon layer comprises a blocking layer configured to reduce the migration of dopant species from the doped silicon layer into the channel layer.

In some embodiments, the carbon doped silicon layer is deposited directly on the doped silicon layer.

In some embodiments, the channel layer is deposited directly on the carbon doped silicon layer.

In some embodiments, an additional carbon doped silicon layer is deposited directly on the channel layer.

In some embodiments, the carbon doped silicon layer is deposited directly on the channel layer.

In some embodiments, an additional doped silicon layer is deposited directly on the carbon doped silicon layer.

In some embodiments, the semiconductor layer stack is deposited by an isothermal deposition process at a deposition temperature selected between 500° C. and 850° C.

In some embodiments, the doped silicon layer comprises an epitaxial doped silicon layer doped with at least one of phosphorus and arsenic.

In some embodiments, the carbon doped silicon layer comprises an epitaxial carbon doped silicon layer.

In some embodiments, the epitaxial carbon doped silicon layer is deposited with a carbon doping concentration between 1×10¹⁷ cm⁻³ and 1×10²¹ cm⁻³.

In some embodiments, the epitaxial carbon doped silicon layer is co-doped with a further dopant, the further dopant having a concentration between 1×10¹⁶ cm⁻³ and 1×10²¹ cm⁻³.

In accordance with examples of the disclosure a method of epitaxially depositing a semiconductor layer stack comprising at least a portion of a vertical channel transistor structure, the method comprising: seating a silicon substrate in a reaction chamber, epitaxially depositing a doped silicon layer on the silicon substrate, epitaxially depositing a carbon doped silicon layer directly on the doped silicon layer, epitaxially depositing a silicon channel layer directly on the carbon doped silicon layer. In such a method, the semiconductor layer stack is deposited by an isothermal chemical vapor deposition process without breaking vacuum within the reaction chamber.

In some embodiments, the method further comprises epitaxially depositing an additional carbon doped silicon layer directly on the silicon channel layer.

In some embodiments, at least one of the carbon doped silicon layer and the additional carbon doped silicon layer is deposited with a carbon doping concentration between 1×10¹⁷ cm⁻³ and 1×10²¹ cm⁻³.

In some embodiments, at least one of the carbon doped silicon layer and the additional carbon doped silicon layer is co-doped with a further dopant, the further dopant having a concentration between 1×10¹⁶ cm⁻³ and 1×10²¹ cm⁻³.

In accordance with examples of the disclosure a method of forming a semiconductor layer stack comprising at least a portion of a vertical channel transistor structure, the method comprising: seating a silicon substrate in a reaction chamber, heating the silicon substrate to a deposition temperature selected between 500° C. and 850° C. The method further includes, epitaxially depositing the semiconductor layer stack by an isothermal chemical vapor deposition process comprising: introducing at least a first silicon precursor and a dopant gas into the reaction chamber to epitaxially deposit a doped silicon layer on the silicon substrate, introducing at least a second silicon precursor and a carbon dopant gas into the reaction chamber to epitaxially deposit a carbon doped silicon layer directly on the doped silicon layer, and introducing at least a third silicon precursor into the reaction chamber to epitaxially deposit a silicon channel layer directly on the carbon doped silicon layer. In such a method, the carbon doped silicon layer forms a blocking layer that reduces the migration of dopant species from the doped silicon layer into silicon channel layer.

In some embodiments, the reaction chamber comprises a quartz assembly including an upper wall and a lower wall, the upper wall extending longitudinally between an injection chamber flange and a longitudinally opposite exhaust chamber flange, the lower wall being below and parallel relative to the upper wall.

In some embodiments, heating the silicon substrate includes: radiantly heating the silicon substrate disposed within a chamber interior of the reaction chamber by employing at least one of an upper heater element array positioned above the upper wall of the reaction chamber and a lower heater element array positioned below the lower wall of the reaction chamber, and maintaining the isothermal chemical vapor deposition process by monitoring and controlling a temperature of at one of the silicon substrate and the semiconductor layer stack thereon by use of a controller in operable communication with one or more temperature sensors and at least one of the upper heater element array and the lower heater element array.

In some embodiments, the carbon doped silicon layer is deposited with a carbon doping concentration between 1×10¹⁷ cm⁻³ and 1×10²¹ cm⁻³.

In some embodiments, the carbon doped silicon layer is co-doped with a further dopant, the further dopant having a concentration between 1×10¹⁶ cm⁻³ and 1×10²¹ cm⁻³.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a cross-sectional view of a portion of a vertical channel transistor structure in accordance with one or more embodiments of the disclosure.

FIG. 2 illustrates a method of forming a semiconductor layer stack comprising at least a portion of a vertical channel transistor structure in accordance with one or more embodiments of the disclosure.

FIG. 3 illustrates a cross-sectional schematic of a semiconductor processing system and an associated reaction chamber that can be employed in the formation of semiconductor layer stacks in accordance with one or more embodiments of the disclosure.

FIGS. 4-6 illustrate cross-sectional views of vertical channel transistor structures including semiconductor layer stacks in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride, and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gases. Exemplary seal gases include noble gasses, nitrogen, and the like. In some cases, the term “precursor” can refer to a compound that participates in the chemical reaction that produces another compound, and particularly to a compound that constitutes a film matrix or a main skeleton of a film. In addition, the term “reactant” can be used interchangeably with the term “precursor.”

As used herein, the term “epitaxial layer” can refer to a substantially single crystalline layer directly on an underlying substantially single crystalline substrate or layer.

As used herein, the term “chemical vapor deposition” can refer to any process wherein a substrate is exposed to one or more volatile precursors (as well as optional additional process gases), which react and/or decompose on a substrate surface to produce a desired deposition.

A number of example materials are given throughout the embodiments of the current disclosure; it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure; it should be noted that the chemical formulas given for each of the example materials should not be construed as limiting and that the non-limiting example materials given should not be limited by a given example stoichiometry.

Various embodiments of the present disclosure relate to methods for forming semiconductor layer stacks for use in the fabrication of vertical channel transistor structures.

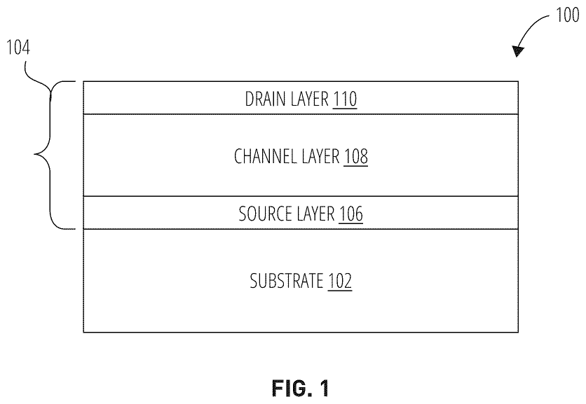

Vertical channel transistors can include a multitude of layers deposited by various deposition techniques. As a non-limiting example, FIG. 1 illustrates a cross-sectional view of a portion of a vertical channel transistor structure 100 including a substrate 102 and a semiconductor layer stack 104 disposed on the substrate 102. The semiconductor layer stack 104 comprises a source layer 106 and a drain layer 110 sandwiching a channel layer 108. The source layer 106 and the drain layer 110 are commonly highly doped layers. Highly doped source/drain layers are commonly employed for a number of reasons, including, but not limited, to enhanced carrier injection, reduce contact resistance, improve on-state performance, and minimize short channel effect. It should be noted that in some examples, the source layer 106 and the drain layer 110 in the semiconductor layer stack 104 can be interchanged, with the drain layer 110 being below the channel layer 108 and the source layer 106 being above the channel layer 108.

The channel layer 108, disposed directly between the highly doped source layer 106 and drain layer 110, is frequently either lightly or undoped. As a non-limiting example, an undoped channel layer may be advantageous, in certain applications, as an undoped (e.g., or intrinsically doped) channel layer can exhibit reduced scattering and improved carrier mobility which can be beneficial to device speed and efficiency. Disadvantageously, during the deposition of the channel layer 108 on the source layer 106 and/or during deposition of the drain layer 110 on the channel layer 108, dopant migration from the high doped source/layers into the channel layer may occur. Such dopant migration can negatively impact device performance of the vertical channel transistor structure. For example, such dopant migration may result in a threshold voltage shift, exacerbate short channel effect, and may lead to higher leakage currents, reducing device performance and increasing device variability.

Accordingly, various embodiments of the present disclosure employ one or more carbon doped silicon layers between highly doped layers and the channel layer. In various embodiments, a single carbon doped silicon layer, or a pair of carbon doped silicon layers are deposited between the highly doped layers of the vertical channel transistor structure and the channel layer. In such embodiments, the carbon doped silicon layer(s) form a blocking layer(s) between the highly doped layers and the channel layer to prevent, or substantially reduce, migration of dopant species from the doped layers into the channel layer.

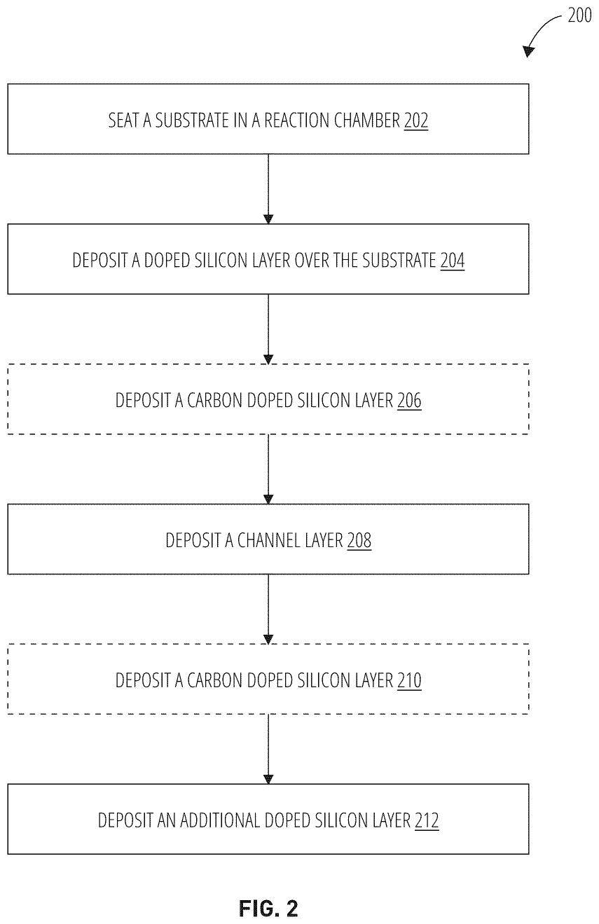

FIG. 2 illustrates an exemplary method 200 for forming a semiconductor layer stack comprising at least a portion of a vertical channel transistor structure in accordance with embodiments of the disclosure. Briefly, method 200 includes the steps of, seating a substrate within a reaction chamber (step 202), depositing a doped silicon layer over the substrate (step 204), depositing a channel layer over the substrate (step 208), depositing a carbon doped silicon layer between a doped silicon layer and the channel layer (step 206 and/or step 210), and depositing an additional doped silicon layer (step 212). In various examples, step 204 for depositing the doped silicon layer and step 212 for depositing the additional doped silicon layer can both comprise the deposition of highly doped source/drain layers.

As described in detail below the carbon doped silicon layer(s) form one or more blocking layers (and are also referred to herein as “blocking layers”) that are configured (i.e., by selection of deposition parameters, composition, thickness, and the like) to reduce the migration of dopant species from the doped silicon layers into the channel layer. As described below, various embodiments include depositing a single carbon doped silicon layer either prior to or post deposition of the channel layer. Various additional embodiments include depositing a pair of carbon doped silicon layers. In such embodiments, a carbon doped silicon layer can be deposited prior to depositing the channel layer, and an additional carbon doped silicon layer can be deposited after depositing the channel layer.

Referring again to FIG. 2, method 200 comprises seating a substrate in a reaction chamber (step 202). In various embodiments, step 202 also comprises heating the substrate to a deposition temperature suitable for forming the semiconductor layer stacks of the present disclosure. Reactions chambers and associated semiconductor processing system suitable for forming the semiconductor layer stacks can include those configured to perform chemical vapor deposition (CVD) processes. In some embodiments, the reaction chamber and associated semiconductor processing system are constructed and arranged for performing epitaxial chemical vapor deposition processes. In certain examples, the reaction chamber and associated semiconductor processing system, are constructured and arranged for performing isothermal chemical vapor deposition processes and/or isothermal epitaxial chemical vapor deposition processes. As used herein the term “isothermal” can refer to a deposition process (e.g., CVD) where a semiconductor layer stack is deposited on a substrate under conditions that maintain a constant deposition temperature throughout the process of depositing the various layers of the semiconductor layer stack. In such “isothermal” deposition processes the deposition temperature (e.g., the substrate temperature during the deposition) may vary from a selected set-point deposition temperature by less than 5%, less than 3%, less than 1%, or less than 0.5%. In addition, the reaction chamber and associated semiconductor processing system are constructed and arranged to enable deposition of the entire semiconductor layer stack by an isothermal chemical vapor deposition process without breaking vacuum within the reaction chamber. For example, the multiple layers of the semiconductor layer stack making up a portion of a vertical channel transistor structure can be deposited by a single deposition process without the need to remove the substrate, and the layers thereon, from the reaction chamber to another reaction chamber.

In various embodiments, the substrates upon which the semiconductor layer stacks of the present disclosure are formed (e.g., by deposition processes) can comprise bulk crystalline substrates, such as, for example, bulk silicon substrates. In some embodiments, the substrates of the present disclosure can include one or more surface layers. In such examples, the surface layers may form a portion of a vertical channel transistor structure. The substrate may include a high carrier mobility surface layer that is employed to increase device performance, such as, for example, a doped silicon germanium (SiGe) surface layer. In some examples, the surface layers on the substrate, in combination with the semiconductor layer stack deposited on the surface layers by the methods disclosed herein, together form the constituent layers of a vertical channel transistor structure. In addition, the substrate may include one or more partially fabricated device structures, such as, for example, logic elements and/or memory elements. In certain embodiments, the substrate may further include one or more dielectric materials, such as, but not limited to silicon oxides, silicon nitrides, and high-k dielectric layers, such as, for example, hafnium oxides, hafnium zirconium oxide, and the like.

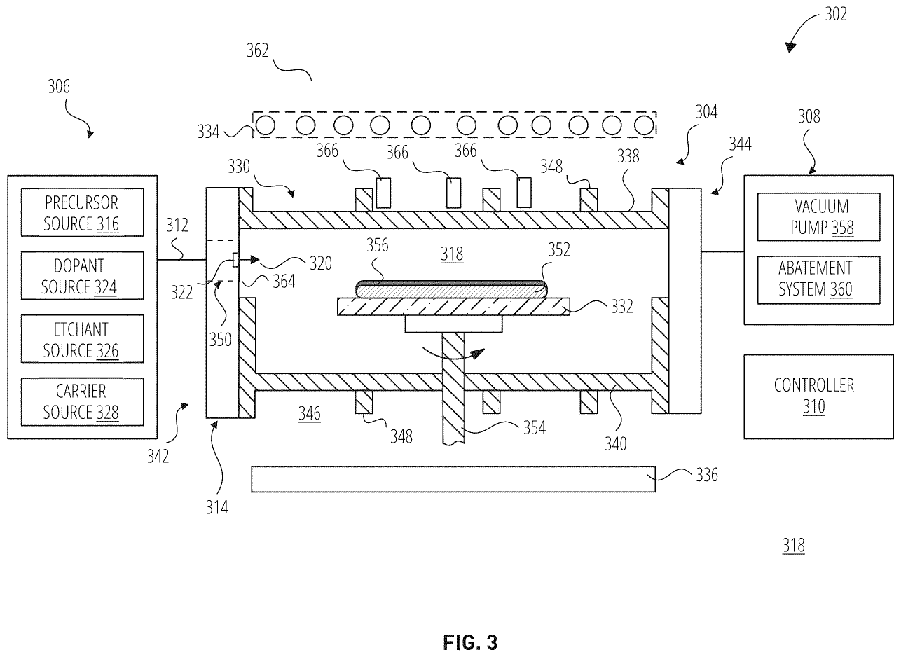

FIG. 3 illustrates a cross-sectional view of a semiconductor processing system 302 (including a reaction chamber 304) that can be employed for forming the semiconductor layer stacks, including the carbon doped blocking layers, of the present disclosure. As illustrated in FIG. 3, the reaction chamber 304 is supplied with a process gas from a gas source assembly 306 and excess process gas and any reaction byproducts are evacuated from the reaction chamber 304 by an exhaust assembly 308.

The gas source assembly 306 is constructed and arrange to provide the process gas (e.g., a vapor phase process gas) to the reaction chamber 304. The process gas can comprise a singular gas or a mix of gases including, but not limited to, precursor gases, dopant gases, etchant gases, and inert gases (e.g., purge gases, carrier gases). The gas source assembly 306 can include various systems, sub-systems, and components (not illustrated) for generating and controlling the flow of the process gas, from the sources included therein, to the process gas supply line 312 which fluidly connects the gas source assembly 306 to the reaction chamber 304 via an injection flange 314.

The gas source assembly 306 includes a precursor source 316 which can include a number of precursor sources. The precursor source 316 can comprises a silicon source including one or more silicon precursors. The process gas provided by the gas source assembly 306 is introduced into the chamber interior 318 (e.g., as indicated by process gas flow 320) through the injection flange 314 including a plurality of injection ports 322.

In various embodiments the silicon precursor comprises one silicon atom per molecule, such as, for example, silane (SiH₄) and/or monochlorosilane (ClH₃Si). Alternatively (or additionally), the silicon precursor can include a high-order silicon precursor having two or more silicon atoms per molecule, or three or more silicon atoms in certain examples. The high-order silicon precursors may include a non-halogenated high-order silicon precursor, such as trisilane and/or tetrasilane. The high-order silicon precursors may include halogenated high-order silicon precursors, such as chlorodisilane, dichlorosilane, trichlorosilane, and tetrachloridesilane. In some embodiments the silicon precursor comprises a silane and/or a halosilane. In some embodiments, the silicon precursor can comprise a hydrogenated silicon precursor. In such embodiments, the hydrogenated silicon precursor can be selected from one or more of silane (SiH₄), disilane (Si₂H₆), trisilane (Si₃H₈), and tetrasilane (Si₄H₁₀). In further embodiments, the silicon precursor can comprise a silicon halide precursor. In such examples the silicon halide precursor can comprise a silicon chloride precursor selected from one or more of monochlorosilane (MCS), dichlorosilane (DCS), trichlorosilane (TCS), hexachlorodisilane (HCDS), octachlorotrisilane (OCTS), and silicon tetrachloride (STC). In further embodiments, the silicon precursor can comprise a silicon iodide precursor. In such examples the silicon halide precursor can comprise a silicon iodide precursor selected from one or more of monoiodosilane, diiodosilane, triiodosilane, and tetraiodosilane.

The precursor source 316 sub-system of the gas source assembly 306 can include one or more germanium sources for providing a germanium precursor to the reaction chamber 304. The germanium precursor can be selected from a germane and/or a germanium halide. For example, the germanium precursor may include a germane, such as germane (GeH₄), digermane (Ge₂H₆), trigermane (Ge₃H₈), or germylsilane (GeH₆Si). In further examples, the germanium precursor may comprise a germanium halide such as GeCl₄, GeCl₂, and GeCl₂H_{2.}

In addition to the precursor source 316, the gas source assembly 306 can include an etchant source 326, and a carrier source 328. The etchant source 326 can include a halide-containing compound. In one aspect, the halide-containing compound is flowed independently from the precursor, such as to provide a purge and/or to remove condensate from within the reaction chamber 304. In another aspect, the halide-containing compound can be co-flowed with one or more other process gases. Examples of suitable halides include chlorine (Cl), e.g., chlorine (Cl₂) gas and hydrochloric (HCl) acid, as well as fluorine (F), e.g., fluorine (F₂) gas and hydrofluoric (HF) acid. The carrier source 328 can be configured to provide an inert carrier gas and/or a purge gas to the reaction chamber 304. Examples of suitable purge/carrier gases may include hydrogen (H₂) gas, nitrogen (N₂) gas, inert gases such as argon (Ar) gas or helium (He) gas, and mixtures thereof.

The gas source assembly 306 can further include a dopant source 324 including one or more dopant gas sources. The dopant source 324 can include various dopant gases such as those suitable for doping silicon layers, including, but not limited to, phosphorus (P), boron (B), carbon (C), and/or arsenic (As) containing dopant gases. In various embodiments, the dopant gases can include one or more silicon p-type dopant gases, such as borane, diborane (B₂H₆), deuterium-diborane (B₂D₆), and boron halides such as BBr₃, BH₂Cl and BCl₂H, for example. In various embodiments, the dopant gases can include one or more silicon n-type dopant gases, such as phosphine (PH₃) and arsine (AsH₃). In various embodiments, the dopant gases can include one or more carbon dopant gases which are introduced into the reaction chamber to enable the deposition of the carbon doped silicon layers (i.e., the block layers) of the present disclosure. In some embodiments, the carbon dopant gas can comprise an alkane or an alkene, such as, for example, methane (CH₄), ethylene (C₂H₄), acetylene (C₂H₂), and propylene (C₃H₆). In some embodiments, the carbon dopant gas can comprise an organosilicon compound, such as, for example, methylsilane (CH₃SiH₃), neopentasilane (Si₅H₁₂), trimethylsilane (C₃H₉Si), and tetramethylsilane (Si(CH₃)₄). In some embodiments, the carbon dopant gas can comprise an organohalide, such as, for example, carbon tetrachloride (CCl₄), trichloromethylsilane (CH₃SiCl₃), dichloromethane (CH₂Cl₂), and tetrachloroethylene (C₂Cl₄)

Referring back to the semiconductor processing system 302 of FIG. 3, the reaction chamber 304 can comprise a cross flow, cold wall epitaxial reaction chamber. In various embodiments, the reaction chamber 304 includes a chamber body 330 and a substrate support 332. The substrate 352 can be heated by use of at least one of an upper heater element array 334 and a lower heater element array 336, as illustrated in FIG. 3. Although a specific arrangement is shown and described herein, it is to be understood and appreciated that the semiconductor processing system 302 and the associated reaction chamber 304 may include other elements and/or omit elements shown and described herein and remain within the scope of the present disclosure.

As illustrated in FIG. 3, the chamber body 330 comprising an upper wall 338, a lower wall 340, as well side walls (not illustrated). The upper wall 338 and the lower wall 340 extend longitudinally between an injection end 342 and a longitudinally opposite exhaust end 344, at least partially defining a chamber interior 318 and a chamber exterior 346. The lower wall 340 is below and parallel to the upper wall 338. In certain examples, the chamber body 330 can be formed from a ceramic material such as sapphire or quartz, for example. The chamber body 330 may include a plurality of external ribs 348. The plurality of external ribs 348 may extend laterally about the chamber exterior 346 and be longitudinally spaced between the injection end 342 and the exhaust end 344 of the chamber body 330. It is also contemplated that, in accordance with certain examples, the chamber body 330 may include no ribs.

In various embodiments, the semiconductor processing system 302 includes an injection flange 314 coupled to the injection end 342 of the chamber body 330. The injection flange 314 includes a front face which is coupled with the injection end 342 of the chamber body 330. The injection flange 314 can include a substrate channel 350 through which a substrate (such as substrate 352) can be loaded and unloaded to and from the chamber exterior 346. The injection flange 314 includes a plurality of injection ports (as illustrated by an exemplary injection port 322 in FIG. 3). The injection flange 314 can further include a gas distribution assembly (not illustrated) including plurality of flow controllers which can be configured to control a flow of the process gas from the gas source assembly 306 to the plurality of injection ports 322 and therethrough to the chamber interior 318.

As illustrated in FIG. 3, a substrate support 332 is disposed within the chamber interior 318. The substrate support 332 can be positioned between the injection end 342 and the exhaust end 344 of the chamber body 330. The substrate support 332 includes a shaft member 354 arranged within the chamber body 330 and configured for rotation about a rotation axis within the chamber interior 318. The substrate support 332 can be formed from an opaque material, such as silicon carbide or a bulk graphite material.

In various embodiments, an upper heater element array 334 can be configured to heat the substrate 352 and/or an epitaxial layer 356 (e.g., a semiconductor layer stack) during deposition on the substrate 352 by radiantly communicating heat into the chamber interior 318. The upper heater element array 334 can include a plurality of upper linear lamps supported above the chamber body 330 (e.g., above the upper wall 338) and optically coupled to the substrate support 332 by the material forming the chamber body 330, e.g., a quartz material. The lower heater element array 336 can be similar to the upper heater element array 334 and can also be configured to heat the substrate 352 and/or the epitaxial layer 356 during deposition on the substrate 352. The lower heater element array 336 can include a plurality of lower linear lamps supported below the chamber body 330 (e.g., below the lower wall 340) and optically coupled to the substrate support 332 by the material forming the chamber body 330. In various embodiments the upper heater element array 334 and/or the lower heater element array 336 may be employed for epitaxially depositing an epitaxial layer 356 on the substrate 352.

In various embodiments, the semiconductor processing system 302 employs one or more temperature sensors to monitor the temperature of the substrate within the chamber interior 318 (and any epitaxial layers 356 thereon). As illustrated in FIG. 3, multiple temperature sensors 366 can be employed to measure the temperature at different points across the substrate. In certain examples, the temperature sensors 366 can comprise pyrometers (e.g., single- , dual- , or tri-pyrometers). The temperature sensors 366 are operatively connected to the controller 310, and the controller 310 is in turn operatively connected to the upper heater element array 334 and/or the lower heater element array 336. The controller 310 can compensate for any variation in the temperature of the substrate (i.e., the deposition temperature) by communicating with the temperature sensors 366 and adjusting the power to the upper heater element array 334 and/or the lower heater element array 336 accordingly to maintain isothermal deposition process conditions. Accordingly, the formation of the semiconductor layer stacks of the present disclosure can comprise, maintaining an isothermal chemical vapor deposition process by monitoring and controlling a temperature of at one of a silicon substrate and a semiconductor layer stack thereon by use of a controller in operable communication with one or more temperature sensors and at least one of the upper heater element array and the lower heater element array.

The semiconductor processing system 302 also includes an exhaust assembly 308. The exhaust assembly 308 can be configured to evacuate the reaction chamber 304 and can include one or more vacuum pumps 358 and an abatement system 360. The vacuum pumps 358 can be fluidly coupled to the reaction chamber 304 and configured to control the pressure within the chamber interior 318. The abatement system 360 can be fluidly coupled to the vacuum pumps 358 and configured to process the flow of residual precursor and/or reaction products issued from the reaction chamber 304. In some embodiments, the exhaust assembly 308 may be configured to maintain environmental conditions within the chamber interior 318 suitable for deposition operations.

The controller 310 includes a processer and memory having instructions recorded on the memory that, when read by the processor, cause the processor to perform processes for depositing an epitaxial layer 356, such as a semiconductor layer stack suitable in the fabrication of vertical channel transistor structures on the substrate 352, as described in detail below.

Referring again to FIG. 2, step 202 of method 200 includes heating the substrate to a suitable deposition. In various embodiments, the substrate is heated to a selected deposition temperature (e.g., a substrate temperature) of less than 850° C., less than 800° C., less than 750° C., less than 700° C., less than 650° C., less than 600° C., less than 550° C., or less than 500° C. In some embodiments, the substrate is heated to a selected deposition temperature between 500° C. and 850° C., or between 550° C. and 750° C., or between 600°C. and 700° C. In some embodiments, the substrate is heated to a selected deposition temperature greater than 500° C. and less than 850° C.

As described above, the deposition processes of present disclosure can include isothermal deposition processes. In such embodiments, the deposition temperature is maintained at a constant temperature, or a substantially constant temperature, during the deposition of the layers constituting the semiconductor layer stacks (including blocking layers) comprising at least a portion of a vertical channel transistor structure. In certain examples, the deposition temperature is maintained at a constant temperature selected between 500° C. and 850° C., or between 550° C. and 750° C., or between 600° C. and 700° C. In some embodiments, the deposition temperature is maintained at constant temperature (i.e., isothermal) by employing the temperature sensors 366, upper heater element array 334 and/or lower heater element array 336, and the controller 310, as described above. In such examples, the deposition temperature is maintained at a temperature selected between 500° C. and 850° C., or between 550° C. and 750° C., or between 600° C. and 700° C. during the deposition of the semiconductor layer stack with a variation from the selected deposition temperature of less than 5 %, less than 3 %, less than 1 %, or less than 0.5 %.

In addition to controlling the temperature of the substrate, the pressure within the reaction chamber can also be regulated. For example, in some embodiments of the disclosure, the pressure within the reaction chamber during the deposition of the various layers of the semiconductor layer stack making up the a portion of the vertical channel transistor structure is less than 760 Torr, less than 350 Torr, less than 250 Torr, less than 50 Torr, less than 25 Torr, less than 10 Torr, or even less than 5 Torr. In some embodiments, the pressure in the reaction chamber is between 5 Torr and 760 Torr, or between 10 Torr and 250 Torr, or between 25 Torr and 200 Torr.

Referring again to FIG. 2, method 200 comprises depositing a doped silicon layer over the substrate (step 204). In some embodiments, the doped silicon layer comprises a highly doped source/drain layer.

In accordance with examples of the disclosure, the doped silicon layer can be either doped p-type or n-type. In such examples, the doped silicon layer can be epitaxially deposited over the substrate by introducing at least a first silicon precursor and a dopant gas into the reaction chamber. The first silicon precursor can comprise one or more of the silicon precursors previously described herein and the dopant gas can comprise one or more of the dopant gases previously described above. The dopant gas may be selected depending on the desired conductivity of the epitaxially deposited doped silicon layer. As a non-limiting example, the doped silicon layer may comprise a n-type layer doped with phosphorus or arsenic, for example. In such examples, the doped silicon layer can be deposited by introducing at least a first silicon precursor and phosphine (PH₃) into the reaction chamber to form a phosphorus doped silicon layer (Si:P). As a further non-limiting example, the doped silicon layer may comprise a p-type layer doped with boron, for example. In such examples, the doped silicon layer can be deposited by introducing at least a first silicon precursor and diborane (B₂H₆) into the reaction chamber to form a boron doped silicon layer (Si:B).

In some embodiments, the doped silicon layer can be epitaxially deposited with a dopant concentration between 1×10¹⁶ to 1×10²¹ cm⁻³. In addition, the doped silicon layer can be epitaxially deposited over the substrate to an average layer thickness of between 1 nanometer (nm) and 1000 nm.

In some embodiments, a single carbon doped silicon layer is deposited to form a blocking layer configured for preventing migration of dopants into the channel layer of the semiconductor layer stack. In such embodiments, the single carbon doped silicon layer can be deposited either prior to or post deposition of the channel layer.

In some embodiments, a single carbon doped silicon layer is deposited prior to depositing the channel layer. The carbon doped silicon layer can be deposited directly on the doped silicon layer (e.g., a source/drain layer), thereby forming a blocking layer which can reduce the migration of dopant species from the doped silicon layer into a subsequently deposited channel layer. The carbon doped silicon layer can be disposed between the doped silicon layer and the channel layer.

Accordingly and referring back to FIG. 2, method 200 can comprise seating a substrate in a reaction chamber (step 202), depositing a doped silicon layer over the substrate (step 204), depositing a carbon doped silicon layer directly on the doped silicon layer (step 206), depositing a channel layer directly the carbon doped silicon layer (step 208), and depositing an additional doped silicon layer on the channel layer (step 212). In this example embodiment, step 210 comprising depositing a carbon doped layer silicon layer on the channel layer is omitted.

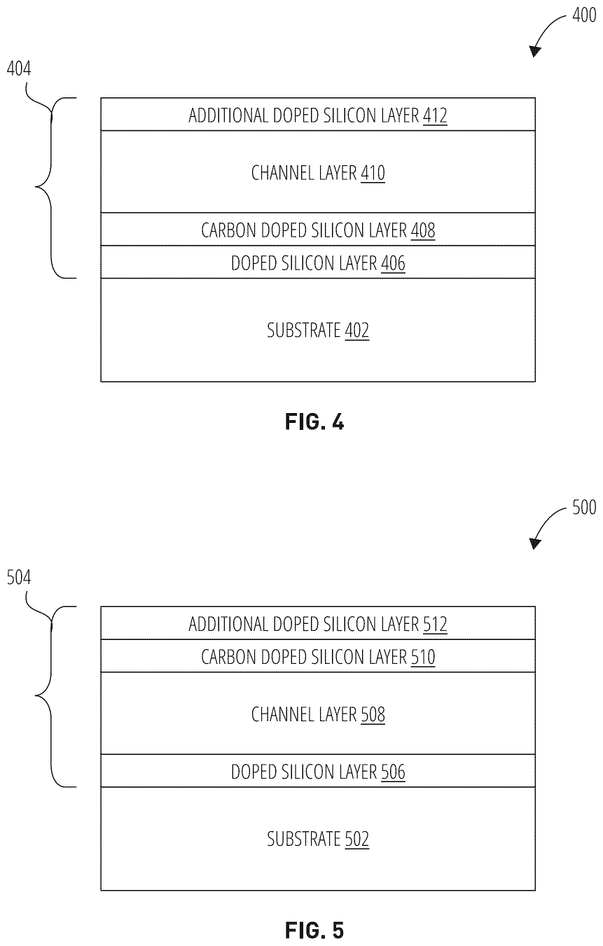

FIG. 4 illustrates a portion of a vertical channel transistor structure 400 including a semiconductor layer stack 404 deposited by the methods described above. The semiconductor layer stack 404 includes a single blocking layer (i.e., carbon doped silicon layer 408), disposed between the doped silicon layer 406 and the channel layer 410. As illustrated in FIG. 4, the portion of a vertical channel transistor structure 400 comprises a substrate 402 and a semiconductor layer stack 404 disposed on the substrate 402. In such embodiments, the semiconductor layer stack 404 comprises a doped silicon layer 406 disposed on the substrate 402, a carbon doped silicon layer 408 disposed on the doped silicon layer 406, a channel layer 410 disposed on the carbon doped silicon layer 408, and an additional doped silicon layer 412 disposed on the channel layer 410.

In some embodiments, a single carbon doped silicon layer is deposited post deposition of the channel layer. In such embodiments, the carbon doped silicon layer can be deposited directly on the channel layer, thereby forming a blocking layer which can reduce the migration of dopant species from a subsequently deposited additional doped silicon layer (e.g., a source/drain layer) on the channel layer. In such embodiments, the carbon doped silicon layer is disposed between the channel layer and an additional doped silicon layer.

Accordingly and referring back to FIG. 2, method 200 can comprise seating a substrate in a reaction chamber (step 202), depositing a doped silicon layer over the substrate (step 204), depositing a channel layer directly the doped silicon layer (step 208), depositing a carbon doped silicon layer directly on the channel layer (step 210), and depositing an additional doped silicon layer on the channel layer (step 212). In this example embodiment, step 206 comprising depositing a carbon doped silicon layer on the doped silicon layer is omitted.

FIG. 5 illustrates a portion of a vertical channel transistor structure 500 including a semiconductor layer stack 504 deposited by the methods described above. The semiconductor layer stack 504 includes a single blocking layer (i.e., carbon doped silicon layer 510) disposed between the channel layer 508 and the additional doped silicon layer 512. As illustrated in FIG. 5, the portion of a vertical channel transistor structure 500 comprises a substrate 502 and a semiconductor layer stack 504 disposed on the substrate 502. In such embodiments, the semiconductor layer stack 504 comprises a doped silicon layer 506 disposed on the substrate 502, a channel layer 508 disposed on the doped silicon layer 506, a carbon doped silicon layer 510 disposed on the channel layer 508, and an additional doped silicon layer 512 disposed on the carbon doped silicon layer 510.

In some embodiments, a pair of carbon doped silicon layer are deposited to form blocking layers configured for preventing, or reducing, migration of dopants into the channel layer of the semiconductor layer stack from both the doped silicon layer (e.g., a first source/drain layer) and an additional doped silicon layer (e.g., a second source/drain layer). In such embodiments, the pair of carbon doped silicon layers are deposited prior to and post deposition of the channel layer.

Accordingly and referring back to FIG. 2, method 200 can comprise seating a substrate in a reaction chamber (step 202), depositing a doped silicon layer over the substrate (step 204), depositing a carbon doped silicon layer directly on the doped silicon layer (step 206), depositing a channel layer directly on the carbon doped silicon layer (step 208), depositing a carbon doped silicon layer (also referred to herein as an additional carbon doped silicon layer) directly on the channel layer (step 210), and depositing an additional doped silicon layer on the carbon doped silicon layer (step 212).

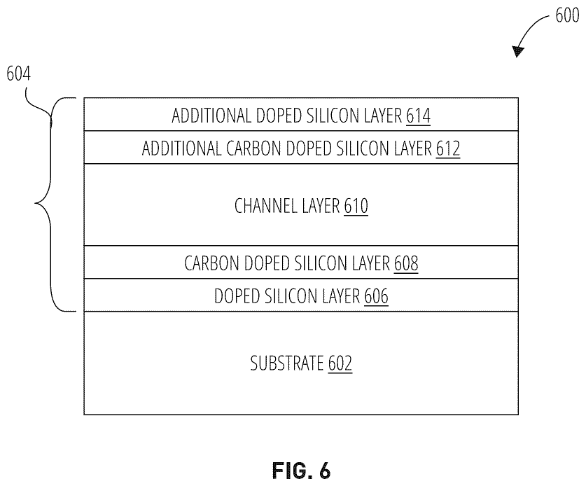

FIG. 6 illustrates a portion of a vertical channel transistor structure 600 including a semiconductor layer stack 604 deposited by the methods described above and includes a pair of blocking layer (i.e., carbon doped silicon layer 608 and additional carbon doped silicon layer 612) disposed either side the channel layer 610 between doped silicon layer 606 and the additional doped silicon layer 614 respectively. As illustrated in FIG. 6, the portion of a vertical channel transistor structure 600 comprises a substrate 602 and a semiconductor layer stack 604 disposed on the substrate 602. In such embodiments, the semiconductor layer stack 604 comprises a doped silicon layer 606 disposed on the substrate 602, a carbon doped silicon layer 608 disposed on the doped silicon layer 606, a channel layer 610 disposed on the carbon doped silicon layer 608, an additional carbon doped silicon layer 612 disposed on the channel layer 610, and an additional doped silicon layer 614 disposed on the additional carbon doped silicon layer 612.

In accordance with examples of the disclosure, the carbon doped silicon layer and the additional carbon doped silicon layer deposited by step 206 and/or step 210 of method 200 can be epitaxially deposited over the substrate by introducing at least a second silicon precursor and a carbon dopant gas into the reaction chamber to epitaxially deposit a carbon doped silicon layer. The second silicon precursor can comprise one or more of the silicon precursors previously described herein and the carbon dopant gas can comprise one or more of the carbon dopant gases previously described above. As a non-limiting example, the carbon doped silicon layers can be deposited by introducing at least a second silicon precursor and a carbon dopant gas comprising an organosilicon compound, such as, for example, methylsilane (CH₃SiH₃), neopentasilane (Si₅H₁₂), trimethylsilane (C₃H₉Si), and tetramethylsilane (Si(CH₃)₄).

In various embodiments, the carbon doped silicon layer(s) can be epitaxially deposited with a carbon doping concentration between 1×10¹⁷ cm⁻³ and 1×10²¹ cm⁻³.

In various embodiments, the carbon doped silicon layer(s) can be epitaxially deposited with both a carbon dopant and a further dopant. In such embodiments, the carbon doped silicon layer(s) can be co-doped with both the carbon dopant and the further dopant. The further dopant in the carbon doped silicon layer can include one or more of the dopants as previously described, such as, for example, phosphorus (P), boron (B), and arsenic (As). As a non-limiting example, the co-doped carbon doped silicon layers can be deposited by introducing at least a second silicon precursor, a carbon dopant gas, and a further dopant gas, the further dopant gas being selected from the one or more of the dopant gases as previously described (e.g., phosphine, arsine, diborane, and the like). In one aspect, the carbon doped silicon layer is co-doped with a further dopant, the further dopant having a concentration between 1×10¹⁶ cm⁻³ and 1×10²¹ cm⁻³.

In various embodiments, the carbon doped silicon layer(s) (e.g., either doped or co-doped) can be epitaxially deposited over the substrate to an average layer thickness of between 0.1 nm and 30 nm.

Referring again to method 200 of FIG. 2, the step of depositing the channel layer can include epitaxially depositing the channel layer (step 208). In such examples, the channel layer can be epitaxially deposited over the substrate by introducing at least a third silicon precursor into the reaction chamber to epitaxially deposit a silicon channel layer. The third silicon precursor can comprise one or more of the silicon precursors previously described herein. As a non-limiting example, the channel layer can comprise an undoped silicon channel layer or an intrinsically doped silicon channel layer. In some embodiments, the channel layer comprises a silicon channel layer epitaxially deposited over the substrate to an average layer thickness of between 1 nm and 1000 nm, or between 50 nm and 500 nm, or between 100 nm and 300 nm.

In accordance with examples of the disclosure, the additional doped silicon layer can be epitaxially deposited over the substrate as previously described above with reference to the doped silicon layer. As a non-limiting example, the additional doped silicon layer may comprise a n-type silicon layer doped with at least one of phosphorus and arsenic. In such examples, the additional doped silicon layer can be deposited by introducing at least a first silicon precursor and phosphine (PH₃) into the reaction chamber to form a phosphorus doped silicon layer (Si:P), as described previously. As a further non-limiting example, the additional doped silicon layer may comprise a p-type silicon layer doped with boron. In such examples, the additional doped silicon layer can be deposited by introducing at least a first silicon precursor and diborane (B₂H₆) into the reaction chamber to form a boron doped silicon layer (Si:B). The additional doped silicon layer can be epitaxially deposited with a dopant concentration between 1×10¹⁶ and 1×10²¹ cm⁻³. In addition, the additional doped silicon layer can be epitaxially deposited over the substrate to an average layer thickness of between 1 nm and 1000 nm.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of forming a semiconductor layer stack comprising at least a portion of a vertical channel transistor structure, the method comprising:
seating a substrate in a reaction chamber;
depositing a doped silicon layer over the substrate;
depositing a channel layer over the substrate; and
depositing a carbon doped silicon layer between the doped silicon layer and the channel layer,
wherein the carbon doped silicon layer comprises a blocking layer configured to reduce the migration of dopant species from the doped silicon layer into the channel layer.

2. The method of claim 1, wherein the carbon doped silicon layer is deposited directly on the doped silicon layer.

3. The method of claim 2, wherein the channel layer is deposited directly on the carbon doped silicon layer.

4. The method of claim 3, wherein an additional carbon doped silicon layer is deposited directly on the channel layer.

5. The method of claim 1, wherein the carbon doped silicon layer is deposited directly on the channel layer.

6. The method of claim 5, wherein an additional doped silicon layer is deposited directly on the carbon doped silicon layer.

7. The method of claim 1, wherein the semiconductor layer stack is deposited by an isothermal deposition process at a deposition temperature selected between 500 ° C. and 850 ° C.

8. The method of claim 1, wherein the doped silicon layer comprises an epitaxial doped silicon layer doped with at least one of phosphorus and arsenic.

9. The method of claim 1, wherein the carbon doped silicon layer comprises an epitaxial carbon doped silicon layer.

10. The method of claim 9, wherein the epitaxial carbon doped silicon layer is deposited with a carbon doping concentration between 1×10¹⁷ cm⁻³ and 1×10²¹ cm⁻³.

11. The method of claim 10, wherein the epitaxial carbon doped silicon layer is co-doped with a further dopant, the further dopant having a concentration between 1×10¹⁶ cm⁻³ and 1×10²¹ cm⁻³.

12. A method of epitaxially depositing a semiconductor layer stack comprising at least a portion of a vertical channel transistor structure, the method comprising:
seating a silicon substrate in a reaction chamber;
epitaxially depositing a doped silicon layer on the silicon substrate;
epitaxially depositing a carbon doped silicon layer directly on the doped silicon layer; and
epitaxially depositing a silicon channel layer directly on the carbon doped silicon layer,
wherein the semiconductor layer stack is deposited by an isothermal chemical vapor deposition process without breaking vacuum within the reaction chamber.

13. The method of claim 12, further comprising epitaxially depositing an additional carbon doped silicon layer directly on the silicon channel layer.

14. The method of claim 13, wherein at least one of the carbon doped silicon layer and the additional carbon doped silicon layer is deposited with a carbon doping concentration between 1×10¹⁷ cm⁻³ and 1×10²¹ cm⁻³.

15. The method of claim 14, wherein at least one of the carbon doped silicon layer and the additional carbon doped silicon layer is co-doped with a further dopant, the further dopant having a concentration between 1×10¹⁶ cm⁻³ and 1×10²¹ cm⁻³.

16. A method of forming a semiconductor layer stack comprising at least a portion of a vertical channel transistor structure, the method comprising:
seating a silicon substrate in a reaction chamber;
heating the silicon substrate to a deposition temperature selected between 500 ° C. and 850 ° C.;
epitaxially depositing the semiconductor layer stack by an isothermal chemical vapor deposition process comprising:
introducing at least a first silicon precursor and a dopant gas into the reaction chamber to epitaxially deposit a doped silicon layer on the silicon substrate;
introducing at least a second silicon precursor and a carbon dopant gas into the reaction chamber to epitaxially deposit a carbon doped silicon layer directly on the doped silicon layer; and
introducing at least a third silicon precursor into the reaction chamber to epitaxially deposit a silicon channel layer directly on the carbon doped silicon layer,
wherein the carbon doped silicon layer forms a blocking layer that reduces the migration of dopant species from the doped silicon layer into silicon channel layer.

17. The method of claim 16, wherein the reaction chamber comprises a quartz assembly including an upper wall and a lower wall, the upper wall extending longitudinally between an injection chamber flange and a longitudinally opposite exhaust chamber flange, the lower wall being below and parallel relative to the upper wall.

18. The method of claim 17, wherein heating the silicon substrate comprises:
radiantly heating the silicon substrate disposed within a chamber interior of the reaction chamber by employing at least one of an upper heater element array positioned above the upper wall of the reaction chamber and a lower heater element array positioned below the lower wall of the reaction chamber, and
maintaining the isothermal chemical vapor deposition process by monitoring and controlling a temperature of at least one of the silicon substrate and the semiconductor layer stack thereon by use of a controller in operable communication with one or more temperature sensors and at least one of the upper heater element array and the lower heater element array.

19. The method of claim 18, the carbon doped silicon layer is deposited with a carbon doping concentration between 1×10¹⁷ cm⁻³ and 1×10²¹ cm⁻³.

20. The method of claim 19, wherein the carbon doped silicon layer is co-doped with a further dopant, the further dopant having a concentration between 1×10¹⁶ cm⁻³ and 1×10²¹ cm⁻³.
